(19) United States
(12) Patent Application Publication
(10) Pub. No.: US 2025/0393372 A1
(43) Pub. Date: Dec. 25, 2025

(54) OPTOELECTRONIC SEMICONDUCTOR COMPONENTS

(71) Applicant: Lextar Electronics Corporation, Hsinchu City (TW)

(72) Inventors: Shiou-Yi KUO, Hsinchu City (TW); Yi-Chan YANG, Hsinchu City (TW); Wen-Syun WANG, Hsinchu City (TW); Fu-Hsin CHEN, Hsinchu City (TW)

(21) Appl. No.: 19/189,088

(22) Filed: Apr. 24, 2025

(30) Foreign Application Priority Data
Jun. 25, 2024 (TW) 113123487

(51) Int. Cl. H10H 29/85; H01L 25/075; H10H 29/24; H10H 29/851; H10H 29/855; H10H 29/856

(52) U.S. Cl. CPC H10H 29/8508; H01L 25/0753; H10H 29/24; H10H 29/8515; H10H 29/8552; H10H 29/856; H10H 29/857

(57) ABSTRACT

An optoelectronic semiconductor component is provided. The optoelectronic semiconductor component includes a base, an electrical connection structure located on the base, a plurality of light-emitting chips located on the electrical connection structure, a plurality of wavelength converters located on the light-emitting chips, and a separation structure located on the electrical connection structure and covering the light-emitting chips and the wavelength converters. The base includes a base material and a plurality of conductor parts. The base material covers the conductor parts which penetrate the base material. The electrical connection structure includes an intermediate part and a plurality of metal parts The intermediate part covers the metal parts. A part of the conductor parts of the base extends into the electrical connection structure and are electrically connected to the metal parts of the electrical connection structure. The metal parts extend into the separation structure and are electrically connected to the light-emitting chips.

### CROSS REFERENCE TO RELATED APPLICATIONS

This application claims priority of Taiwan Patent Application No. 113123487, filed on Jun. 25, 2024, the content of the entirety of which is incorporated by reference herein.

### BACKGROUND OF THE DISCLOSURE

### Field of the Disclosure

The present disclosure relates to an optoelectronic semiconductor component, and, in particular, to an optoelectronic semiconductor component including a light source structure with multiple pixels.

### Description of the Related Art

Semiconductor components have been widely used, and the research and development of related materials are also continuously being carried out. For example, semiconductor materials that include group III and group V elements can be applied to various optoelectronic semiconductor components, such as light-emitting chips (e.g., light-emitting diodes or laser diodes), light-absorbing chips (e.g., photodetectors or solar cells), and power devices (e.g., switches or rectifiers), which can be used in fields such as lighting, medical, display, automotive, communication, sensing, and power systems. With the development of science and technology, the size of the optoelectronic semiconductor components is gradually becoming smaller and there are still many technical research and development needs for optoelectronic semiconductor components. Although existing optoelectronic semiconductor components generally meet a variety of needs, they are not entirely satisfactory in all respects and still require further improvement.

### BRIEF SUMMARY OF THE DISCLOSURE

According to the present disclosure, an optoelectronic semiconductor component comprises a base, and electrical connection structure, a plurality of light emitting chips, a plurality of wavelength conversion members, and a separation structure. The base includes a base material and a plurality of conductive parts. The base material covers the conductive parts and the conductive parts penetrate the base material. The electrical connection structure locates on the base and includes an intermediate part and a plurality of metal parts. The intermediate part covers the meal parts. The plurality of light emitting chips locate on the electrical connection structure. The plurality of wavelength conversion members locate on the light emitting chips. Each one of the wavelength conversion members covers the respective one of the light emitting chips. The separation structure locates on the electrical connection structure and covers the light emitting chips and the wavelength converting members. Some of the conductive parts of the base extend into the intermediate part to electrically connect to the metal parts, and the metal parts extend into the separation structure to electrically connecting to the light emitting chips.

### BRIEF DESCRIPTION OF THE DRAWINGS

FIG. 1 is a schematic cross-sectional view of an optoelectronic semiconductor component according to some embodiments of the present disclosure.

FIG. 2 is a schematic cross-sectional view of a light-emitting chip according to some embodiments of the present disclosure.

FIG. 3 is a schematic cross-sectional view of an optoelectronic semiconductor component according to some embodiments of the present disclosure.

FIG. 4 is a schematic cross-sectional view of an optoelectronic semiconductor component according to some embodiments of the present disclosure.

FIG. 5 is a schematic cross-sectional view of an optoelectronic semiconductor component according to some embodiments of the present disclosure.

FIG. 6 is a schematic top view of an optoelectronic semiconductor component according to some embodiments of the present disclosure.

FIG. 7 is a schematic bottom view of an optoelectronic semiconductor component according to some embodiments of the present disclosure.

FIG. 8 is a schematic cross-sectional view along the line A-A′ of the optoelectronic semiconductor component according to some embodiments of the present disclosure shown in FIG. 6 and FIG. 7.

### DETAILED DESCRIPTION OF THE DISCLOSURE

The following disclosure provides many different embodiments, or examples, for implementing different components of the provided subject matter. Specific examples of components and arrangements are described below to simplify the illustration of the present disclosure. These are, of course, merely examples and are not intended to limit the present disclosure. For example, the formation of a first component over or on a second component in the description that follows may include embodiments in which the first and second components are formed in direct contact, and may also include embodiments in which additional components may be formed between the first and second components, such that the first and second components may not be in direct contact. In addition, the present disclosure may repeat reference numerals and/or letters in the various examples. This repetition is for the purpose of simplicity and clarity and does not indicate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The component may be otherwise oriented (rotated 90 degrees or at other orientations) and the spatially relative descriptors used herein may likewise be interpreted accordingly.

In the present disclosure, the terms “about”, “substantially”, or the like, represents within 10%, 5%, 3%, 2%, 1%, or 0.5%, of a given value or range. The given value herein is an approximate value, that is, even though there is no specific description of “about” or “substantially”, the given value implicitly includes the meaning of “about” or “substantially”.

It should be understood that when a component or layer is referred to as being “connected to” another component or layer, it can be directly connected to this other component or layer, or intervening components or layers may be present. In contrast, when a component is referred to as being “directly connected to” another component or layer, there are no intervening components or layers present.

The electrical connection or coupling described in this disclosure may refer to direct connection or indirect connection. In the case of direct connection, the endpoints of the components on the two circuits are directly connected or connected to each other by a conductor line segment, while in the case of indirect connection, there are switches, diodes, capacitors, inductors, resistors, other suitable components, or a combination of the above components between the endpoints of the components on the two circuits, but the intermediate component is not limited thereto.

The words “first”, “second”, “third”, “fourth”, “fifth”, and “sixth” are used to describe components. They are not used to indicate the priority order of or advance relationship, but only to distinguish components with the same name.

Unless defined otherwise, all terms (including technical and scientific terms) used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the disclosure and the background or the context of the disclosure, and should not be interpreted in an idealized or overly formal manner unless so defined.

It should be noted that the technical features in different embodiments described in the following can be replaced, recombined, or mixed with one another to constitute another embodiment without departing from the spirit of the present disclosure.

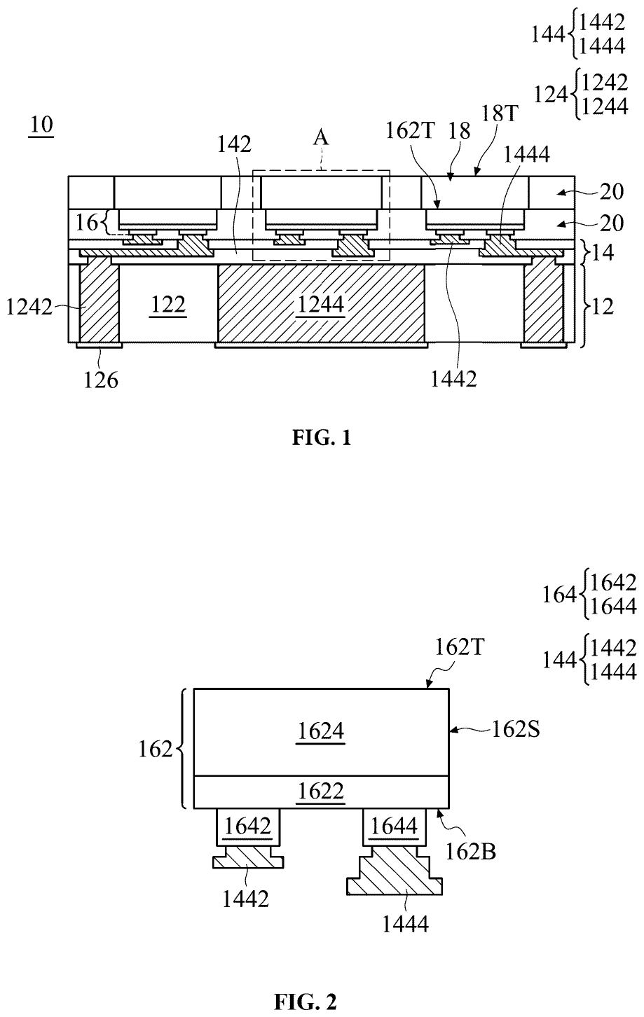

FIG. 1 is a schematic cross-sectional view of an optoelectronic semiconductor component 10 according to some embodiments of the present disclosure. As shown in FIG. 1, the optoelectronic semiconductor component 10 includes a base 12, an electrical connection structure 14, a plurality of light emitting chips 16, a plurality of wavelength conversion members 18, and a separation structure 20. The base 12 includes a base material 122 and a plurality of conductive parts 124 covered by the base material 122, and the plurality of conductive parts 124 penetrate the base material 122. The electrical connection structure 14 locates on the base 12 and includes an intermediate part 142 and a plurality of metal parts 144. The intermediate part 142 covers the metal parts 144, and the metal parts 144 are separated from each other by the intermediate part 142. The light emitting chips 16 locate on the electrical connection structure 14. The wavelength conversion members 18 locate on the light emitting chips 16, and each of the wavelength conversion members 18 covers the respective one of the light emitting chips 16. The separation structure 20 locates on the electrical connection structure 14 and covers both the light emitting chips 16 and the wavelength conversion members 18 but exposes the top surfaces 18T of the wavelength conversion members 18. It is noted that a portion of the conductive parts 124 of the base 12 extend into the electrical connection structure 14 to electrically connect to the metal parts 144 of the electrical connection structure 14, and the metal parts 144 extend into the separation structure 20 to electrically connect to the light emitting chips 16. When the current is provided on the optoelectronic semiconductor component 10, the light emitted from the light emitting chips 16 travel into the wavelength conversion members 18 and emission outwardly from the top surface 18T of the wavelength conversion members 18.

In some embodiments, the base material 122 may include insulating materials, for example, epoxy resin, polyimide (PI), silicone resin, or a combination thereof. In some embodiments, the base material 122 may be added with some fillers to block, absorb, or reflect the light emitted from the light emitting chips 16. The fillers may be titanium oxide (TiOₓ), silicon oxide (SOₓ), pigments, other suitable materials or a combination thereof.

In some embodiments, the conductive parts may include silver (Ag), copper (Cu), gold (Au), aluminum (Al), molybdenum (M o), titanium (Ti), tungsten (W), zinc (Zn), nickel (Ni), ferrum (Fe), platinum (Pt), palladium (Pd), chromium (Cr), tin (Sn), an alloy thereof, or a combination thereof. In some embodiments, each of the conductive parts 124 may be a bulk, such as a cylinder or a block, with a predetermined thickness, for example, ranged from 2 micrometers (μm) to 100 μm. When the thickness of the conductive part 124 is lower than 2 μm, the base 12 may not stably support the electrical connection structure 14, the light emitting chips 16, the wavelength conversion members 18, and the separation structure 20 thereon. When the thickness of the conductive part 124 is greater than 100 μm, the volume of the optoelectronic semiconductor component 10 may become larger, which is not benefit to fit the requirement of the miniature applications.

In some embodiments, the conductive part 124 may include the electric conductive part 1242 and the thermal conductive part 1244. The electric conductive part 1242 is used as a current-flow path and the thermal conductive part 1244 is used as a heat-dissipation path. Specifically, the electric conductive part 1242 extends into the electrical connection structure 14 to electrically connect to the metal part 144, and then electrically connects to the light emitting chip 16 via the metal part 144, while the thermal conductive part 1244 does not electrically connect to the light emitting chip 16. In some embodiments, the conductive part 124 may not include the thermal conductive part 1244.

In some embodiments, the base material 122 may be formed by coating, molding, other suitable process, or a combination thereof. The conductive part 124 may be formed by a deposition process, such as evaporation, sputtering or plating, a printing process, a vacuum spray coating, other suitable processes, or a combination thereof. In some embodiments, the electric conductive part 1242 and the thermal conductive part 1244 may be formed in one process to simplify the manufacturing flow. In this embodiment, the base material 122 is the epoxy molding compound (EMC) with black pigments, and the conductive parts 124 are copper blocks formed by plating.

In some embodiments, the intermediate part 142 may be a single layer structure. In some embodiments, the intermediate part 142 may be a multilayer structure as shown in FIG. 1. In some embodiments, the intermediate part 142 may include insulating materials such as epoxy, polyimide (PI), polybenzoxazole (PBO), benzocyclobutene (BCB), silicone, silicon oxide (SiOₓ), silicon nitride (SiNₓ) or the combination thereof. In some embodiments, the intermediate part 142 may be formed by a deposition process, such as evaporation, sputtering, or plating, a coating process, a molding process, other suitable processes, or a combination thereof.

In some embodiments, the metal parts 144 may include tin (Sn), copper (Cu), silver (Ag), gold (Au), nickel (Ni), molybdenum (Mo), platinum (Pt), palladium (Pd), titanium (Ti), chromium (Cr), tungsten (W), tantalum (Ta), aluminum (Al), germanium (Ge), an alloy thereof, or a combination thereof. In this embodiment, the intermediate part 142 is PBO, the metal parts 144 are metal film stacks of Cr/Pt/Au or Ti/Cu/Ti formed by the sputtering process.

In some embodiments, the light emitting chips 16 may include light emitting diode (LED) or laser diode (LED). In this embodiment, the light emitting chips 16 are LEDs with sub-millimeter scale, i.e., mini LED.

In some embodiments, the wavelength conversion member 18 may include a transparent material comprising a wavelength conversion material. For example, the transparent material may be resin or glass, and the wavelength conversion material may be fluorescent particle or quantum dot (QD).

In some embodiments, the separation structure 20 may be a single layer structure. In some embodiments, the separation structure 20 may be a multilayer structure, for example, layers sequentially stack from bottom to top in the vertical direction (as shown in FIG. 1) or from left to right in the lateral direction. In some embodiments, the separation structure 20 may include epoxy, PI, silicone, metal, other suitable materials, or a combination thereof. In some embodiments, some fillers may be added into the separation structure 20. The fillers may be, for example, TiOₓ, SiOₓ, pigments, other suitable material, or the combination thereof. In some embodiments, the separation structure 20 can block, reflect, or absorb the light emitted from the light emitting chips 16. In this embodiment, the separation structure 20 comprises epoxy molding compound (EMC) with white color due to the TiO₂ fillers. In some embodiments, the material of the separation structure 20 is the same as that of the base material 122.

In some embodiments, each wavelength conversion member 18 is located on the respective one of the light emitting chips 16, for example, each wavelength conversion member 18 covers an upper surface 162T of the respective one of light emitting chips 16. That is, one wavelength conversion member 18 covers one upper surface 162T.

In some embodiments, each of the metal parts 144 connects to different one of the light emitting chips 16. In some embodiments, one metal part 144 may be connected to at least two of the light emitting chips 16.

In some embodiments, the base 12 further includes a plurality of bonding pads 126 electrically connected to the corresponding one of the conductive parts 124 respectively, and the conductive parts 124 are located between the bonding pads 126 and electrical connection structure 14. In some embodiments, the manufacturing method and the material of the bonding pads 126 may be similar to or the same as the conductive parts 124.

FIG. 2 is an enlarged schematic diagram of the area A in FIG. 1.

As shown in FIG. 2, the light emitting chips 16 may include light emitting structure 162 and electrode structure 164. The light emitting structure 162 has the upper surface 162T, lower surface 162B, and side surface 162S. The upper surface 162T and the lower surface 162B are opposite to each other, and the side surface 162S connects the upper surface 162T to the lower surface 162B. The electrode structure 164 is located on the lower surface 162B of the light emitting structure 162. The light emitting structure 162 may include an epitaxial stack 1622 and a substrate 1624. Specifically, the epitaxial stack 1622 is located between the substrate 1624 and the electrode structure 164, and the upper surface 162T of the light emitting structure 162 is constitutes by the substrate. In some embodiments, the light emitting chip 16 may not include the substrate 1624, such as thin film chip, and the upper surface 162T of the light emitting structure 162 is constituted by the epitaxial stack 1622

In some embodiments, the epitaxial stack 1622 may include III-V compound materials such as aluminum (Al), gallium (Ga), arsenic (As), phosphorus (P), indium (In), or nitrogen (N). Specifically, in some embodiments, the III-V compound materials may be binary compound semiconductor (e.g., GaAs, GaP, GaN or InP), ternary compound semiconductor (e.g., InGaAs, AlGaAs, GaInP, AlInP, InGaN or AlGaN), or quaternary compound semiconductor (e.g., AlGaInAs, AlGaInP, AlInGaN, InGaAsP, InGaAsN or AlGaAsP).

In some embodiments, the substrate 1624 may include silicon (Si), diamond, silicon carbide (SiC), sapphire, gallium oxide (Ga₂O₃), gallium phosphide (GaP), gallium arsenide (GaAs), aluminum gallium arsenide (AlGaAs), other III-V compound, other suitable substrate or a combination thereof.

In some embodiments, the electrode structure 164 may include electrically conductive material, such as metal, conductive nitride, conductive oxide, similar materials or a combination thereof. For example, the metal may be Au, Ni, Pt, Pd, iridium (Ir), Ti, Cr, W, Al, Cu, beryllium (Be), Ge, Zn, Sn, an alloy thereof or the combination thereof; the conductive nitride may be titanium nitride (TIN); conductive oxide may be indium tin oxide (ITO) or indium zinc oxide (IZO). In some embodiments, the electrode structure 164 may include a first electrode 1642 and a second electrode 1644 with a different polarity from the first electrode 1642. For example, the first electrode 1642 is a p-type electrode and the second electrode 1644 is a n-type electrode.

In some embodiments, the epitaxial stack 1622 may include a first-type semiconductor layer, an active layer, and a second-type semiconductor layer sequentially stacked (not shown). The first-type semiconductor layer and the second-type semiconductor layer have different conductive type. For example, the first-type semiconductor layer is p-type layer and the second-type semiconductor layer is n-type layer. In some embodiments, the first electrode 1642 and the second electrode 1644 are electrically connected to the first-type semiconductor layer and the second-type semiconductor layer of the epitaxial stack 1622 respectively. When current is injected into the electrode structure 164, the electrons and holes provided by the first-type semiconductor layer and the second-type semiconductor layer recombine in the active layer, and then the light is emitted toward a direction away from the electrode structure 164, e.g., the upper surface 162T and side surface 162S.

Referring to FIG. 1 and FIG. 2. In some embodiments, in a cross-sectional view, one light emitting chip 16 electrically connects to two metal parts 144, and the two metal parts 144 have different maximum widths in a lateral direction. For example, in the lateral direction, a boundary of one of the two metal parts 144 exceeds to a boundary of the light emitting chip 16, while a boundary of the other one of the two metal parts 144 does not exceed to a boundary of the light emitting chip 16. In some embodiments, in a cross-sectional view, one light emitting chip 16 electrically connects to two metal parts 144, and the two metal parts 144 have different maximum thickness in a vertical direction. For example, in the vertical direction, a distance between one of the two metal parts 144 and the base 12 is smaller than that between the other one of the two metal parts 144 and the base 12, i.e., the vertical spacing between one of the two metal parts 144 and the base 12 is different from the vertical spacing between the other one of the two metal parts 144 and the base 12. In some embodiments, when the intermediate part 142 is the multilayer structure, the intermediate part 142 and the metal parts 144 may be formed alternatively to make the metal parts 144 have different maximum width and/or different maximum thickness.

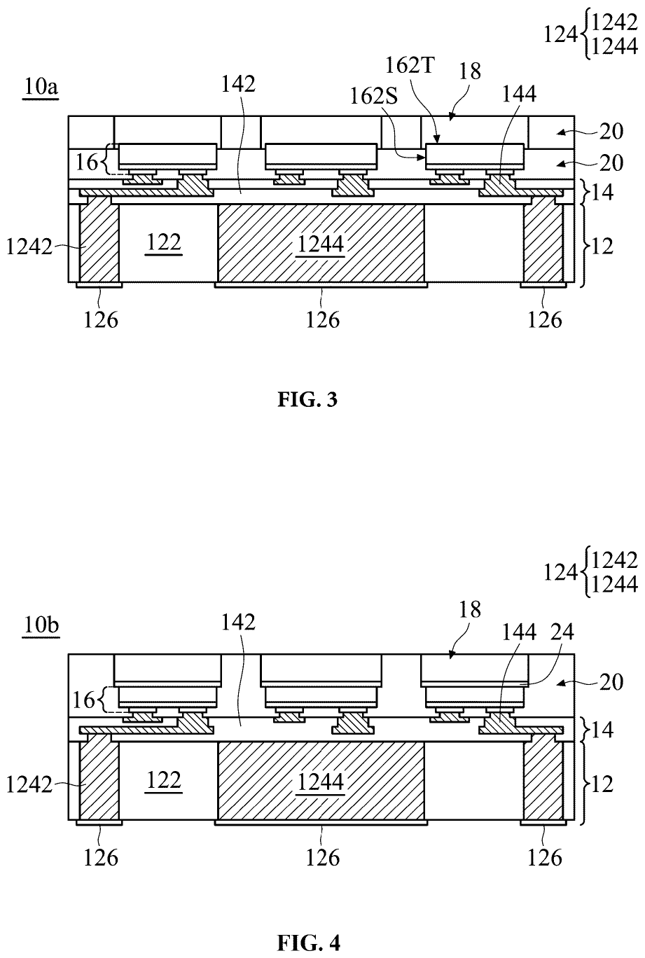

FIG. 3 is a schematic cross-sectional view of an optoelectronic semiconductor component 10a according to some embodiments of the present disclosure. The components, structures, materials, functions, configurations and connection methods of the components of the embodiments shown in FIG. 3 are similar to those of the embodiment shown in FIG. 1. To simplify the description, the same symbols are used to mark the same elements in the following embodiments, and the description is mainly focused on the differences between the various implementation methods without repeating the repeated parts.

As shown in FIG. 3, the optoelectronic semiconductor component 10a includes a base 12, an electrical connection structure 14, a plurality of light emitting chips 16, a plurality of wavelength conversion members 18, and a separation structure 20. The difference between the optoelectronic semiconductor component 10a and the optoelectronic semiconductor component 10 is that the light emitting chips 16 are partially embedded in the wavelength conversion members 18. Specifically, the wavelength conversion members 18 covers the upper surface 162T of the corresponding one of the light emitting chips 16 and extends toward the base 12 to partially cover the side surface 162S of the corresponding one of the light emitting chips 16. Since the contact area between the wavelength conversion member 18 and the light emitting chips 16 is increased, the area that the light emitted from the light emitting chips 16 entering the wavelength conversion member 18 is also increased, thereby the wavelength conversion efficiency is improved. In this embodiment, each of the light emitting chips 16 is partially embedded in the corresponding one of the wavelength conversion members 18. In other embodiments, only a part of the light emitting chips 16 are partially embedded in the corresponding one of the wavelength conversion members 18.

FIG. 4 is a schematic cross-sectional view of an optoelectronic semiconductor component 10b according to some embodiments of the present disclosure. As shown in FIG. 4, the optoelectronic semiconductor component 10b includes a base 12, an electrical connection structure 14, a plurality of light emitting chips 16, a plurality of wavelength conversion members 18, and a separation structure 20. The difference between the optoelectronic semiconductor component 10b and the optoelectronic semiconductor component 10 is that there is a bonding layer 24 between the wavelength conversion member 18 and the corresponding one of the light emitting chips 16. The bonding layer 24 can increase the bonding strength between the wavelength conversion member 18 and the light emitting chips 16, thereby reducing the risk of reliability issues caused by their separation.

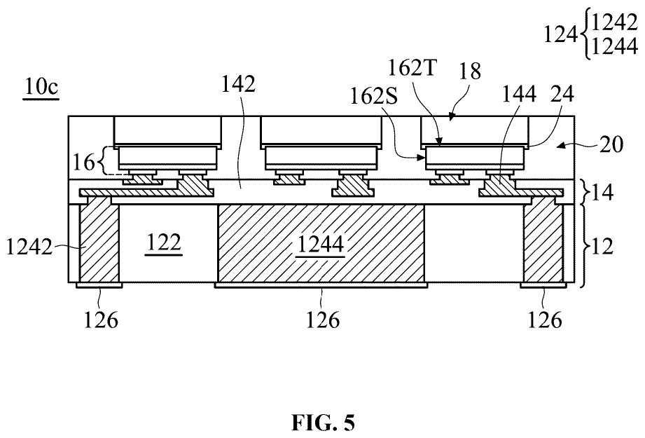

FIG. 5 is a schematic cross-sectional view of an optoelectronic semiconductor component 10c according to some embodiments of the present disclosure. As shown in FIG. 5, the optoelectronic semiconductor component 10c includes a base 12, an electrical connection structure 14, a plurality of light emitting chips 16, a plurality of wavelength conversion members 18, and a separation structure 20. The difference between the optoelectronic semiconductor component 10c and the optoelectronic semiconductor component 10 is that, there is a bonding layer 24 between the wavelength conversion member 18 and the corresponding one of the light emitting chips 16 and the corresponding one of the light emitting chips 16 is at least partially embedded in the bonding layer 24. Specifically, the bonding layer 24 covers the upper surface 162T of the corresponding one of the light emitting chips 16 and extends toward the base 12 to partially cover the side surface 162S of the corresponding one of the light emitting chips 16. Since the contact area between the bonding layer 24 and the corresponding one of the light emitting chip 16 is increased, the bonding strength between the bonding layer 24 and the corresponding one of the light emitting chip 16 is further improved. In this embodiment, each of the light emitting chips 16 is partially embedded in the corresponding one of the bonding layers 24. In other embodiments, only a part of the light emitting chips 16 are partially embedded in the corresponding one of the bonding layers 24.

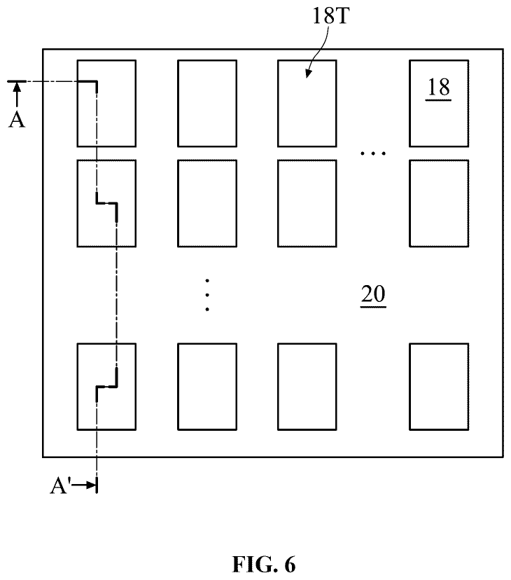

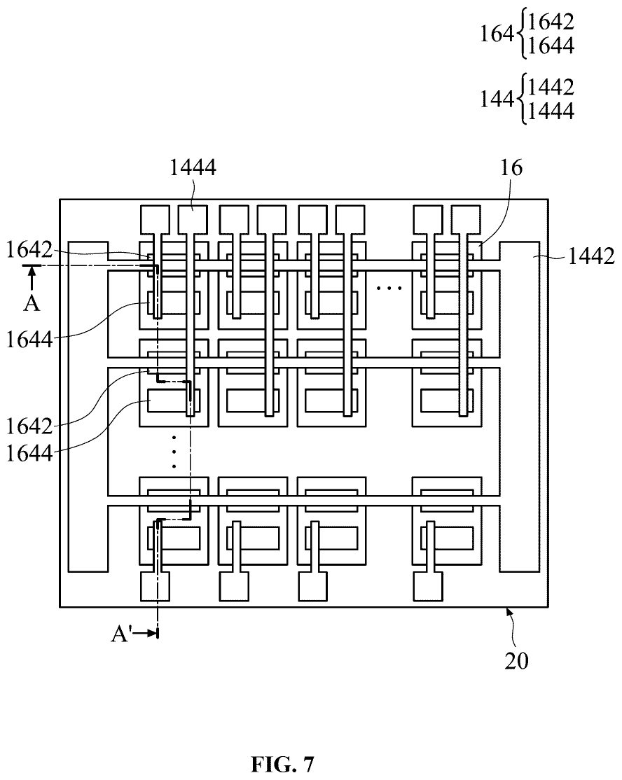

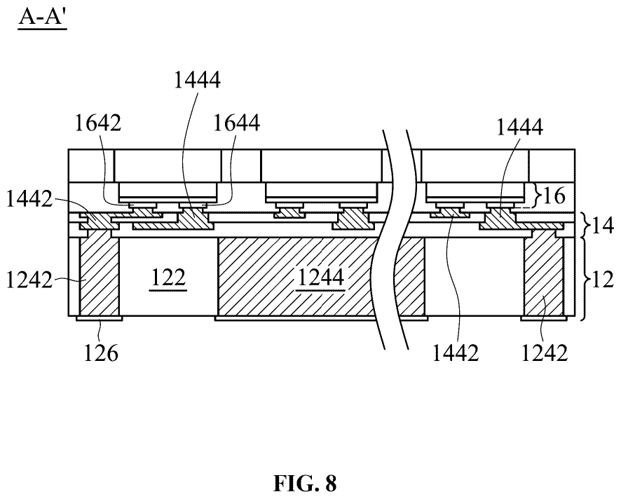

Please refer to FIGS. 6, 7, and 8 showing the circuit configuration of the optoelectronic semiconductor component 10. FIG. 6 is a schematic top view of the optoelectronic semiconductor component 10. FIG. 7 is a schematic bottom view of the optoelectronic semiconductor component 10. FIG. 8 is a schematic cross-sectional view along the line A-A′ in FIG. 6 and FIG. 7. It should be noted that FIG. 7 only shows the outline of the separation structure 20, the light emitting chips 16 and the metal parts 144 of the optoelectronic semiconductor component 10, and other elements are omitted in order to illustrate the layout of the light emitting chips 16 and the metal parts 144.

As shown in FIG. 6, the separation structure 20 covers a plurality of wavelength conversion members 18 which are spaced apart from each other and arranged in an array. An top surface 18T of each of the wavelength conversion members 18 is exposed from the separation structure 20 to serve as an emission surface of the optoelectronic semiconductor component 10, and two adjacent top surfaces 18T are departed from each other by the separation structure 20. In other words, the optoelectronic semiconductor component 10 includes a plurality of emission surfaces arranged at intervals from each other.

As shown in FIG. 7, a plurality of light emitting chips 16 are arranged at intervals in an array. The separation structure 20 covers the plurality of light emitting chips 16 and exposes the electrode structure 164 of each of the plurality of light emitting chips 16. Each of the plurality of light emitting chips 16 is respectively under the corresponding one of the plurality of wavelength conversion members 18. In other words, the plurality of light emitting chips 16 and the plurality of wavelength conversion members 18 have the same arrangement. The electrode structure 164 of each of the plurality of light emitting chips 16 includes a first electrode 1642 and a second electrode 1644. The metal parts 144 include a first metal part 1442 and a plurality of second metal parts 1444. The first electrode 1642 of each of the plurality of light emitting chips 16 is connected to the first metal part 1442, and the second electrode 1644 of each of the plurality of light emitting chips 16 is respectively connected to the corresponding one of the second metal parts 1444. That is, all the light emitting chips 16 share the first electrode 1642, thereby simplifying the design of the electrical connection layout of the optoelectronic semiconductor component 10.

As shown in FIG. 8, the first electrode 1642 and the second electrode 1644 of each of the plurality of light emitting chips 16 are connected to the electric conductive part 1242 of the base 12 by the first metal part 1442 and second metal part 1444 respectively. In other words, the electrical terminal position of the light emitting chip 16 (i.e. the electrode structure 164) can be adjusted and extended to the desired position (i.e. the electric conductive part 1242) by the electrical connection structure 14, thereby improving the design flexibility of the electrical connection layout of the light emitting chip 16.

The present disclosure uses metal parts made of metal film stack to form the electrical connection path between the light emitting chips, and then combines a base material and bulk conductive parts to form a base with supporting strength, which can improve the design accuracy of the electrical connection, and be able to deal with the high complexity and high precision process requirements caused by the small electrode size and the rapidly increasing number of light-emitting chips (the number reaches 100 or even more than 500) when the size of the light-emitting chip is miniaturized (for example, a sub-millimeter chip (mini chip) or a micro chip). In addition, using the molded package with a separation structure and a plurality of wavelength conversion members can further meet the application of multi-pixel components (such as an adaptive driving beam (ADB) light source structure). Compare with the conventional method of forming the circuit route on the supporting substrate first and then electrically connecting the light emitting chip to the supporting substrate by welding, eutectic bonding or glue bonding, the embodiments of present disclosure can not only complete the high-precision electrical connection circuit, but also reduce the overall volume of components more effectively and meet the demand for thinning.

Although the embodiments of the present disclosure and advantages thereof have been disclosed above, it should be understood that those skilled in the art can make changes, substitution, and modifications without departing from the spirit and scope of the present. In addition, the protection scope of the present disclosure is not limited to the processes, machines, manufacturing, material compositions, devices, methods and steps in the specific embodiments described in the specification. A person skilled in the art of the present disclosure can understand from the contents of the embodiments of the present disclosure that any process, machine, manufacturing, material composition, device, method and step currently or developed in the future, as long as it can be achieve substantially the same function or obtain substantially the same result as the embodiments described herein, can be used in accordance with the embodiments of the present disclosure. In addition, the scope for protecting the present disclosure should be defined according to the scope of the appended claims.

What is claimed is:

1. An optoelectronic semiconductor component, comprising:
a base includes a base material and a plurality of conductive parts, the base material covers the conductive parts and the conductive parts penetrate the base material;
an electrical connection structure locates on the base and includes an intermediate part and a plurality of metal parts, and the intermediate part covers the metal parts;
a plurality of light emitting chips locate on the electrical connection structure;
a plurality of wavelength conversion members locates on the light emitting chips, each one of the wavelength conversion members covers a respective one of the light emitting chips; and
a separation structure locates on the electrical connection structure and covers the light emitting chips and the wavelength conversion members;
wherein some of the conductive parts of the base extend into the intermediate part to electrically connect to the metal parts, and the metal parts extend into the separation structure to electrically connect to the light emitting chips.

2. The optoelectronic semiconductor component as claimed in claim 1, wherein
the base further includes a plurality of bonding pads which are electrically connected to one of the conductive parts respectively, and the conductive parts are between the bonding pads and the electrical connection structure.

3. The optoelectronic semiconductor component as claimed in claim 1, wherein
each one of the light emitting chips including a light emitting structure and an electrode structure, the electrode structure is between the light emitting structure and the electrical connection structure, the light emitting structure has an upper surface, a lower surface opposite to the upper surface, and a side surface between the upper surface and the lower surface, wherein each one of the wavelength conversion members covers the upper surface of the respective one of the light emitting chips.

4. The optoelectronic semiconductor component as claimed in claim 1, wherein
at least one of the light emitting chips is partially embedded in one of the wavelength conversion members covers thereon.

5. The optoelectronic semiconductor component as claimed in claim 1, further including a bonding layer between one of the wavelength conversion members and the respective one of the light emitting chips.

6. The optoelectronic semiconductor component as claimed in claim 5, wherein
the respective one of the light emitting chips is partially embedded in the bonding layer.

7. The optoelectronic semiconductor component as claimed in claim 1, wherein
the separation structure reflects the light emitted from the light emitting chips.

8. The optoelectronic semiconductor component as claimed in claim 1, wherein
the separation structure absorbs the light emitted from the light emitting chips.

9. The optoelectronic semiconductor component as claimed in claim 1, wherein
the separation structure includes fillers.

10. The optoelectronic semiconductor component as claimed in claim 1, wherein
the separation structure includes multilayers.

11. The optoelectronic semiconductor component as claimed in claim 1, wherein
the material of the separation structure is the same as that of the base material.

12. The optoelectronic semiconductor component as claimed in claim 3, wherein
the light emitting structure includes a substrate and an epitaxial stack between the substrate and the electrode structure.

13. The optoelectronic semiconductor component as claimed in claim 3, wherein
the light emitting structure includes an epitaxial stack and the upper surface of the light emitting structure is composed of the epitaxial stack.

14. The optoelectronic semiconductor component as claimed in claim 1, wherein
each of the wavelength conversion members has a top surface exposed from the separation structure.

15. The optoelectronic semiconductor component as claimed in claim 14, wherein
in a top view of the optoelectronic semiconductor component, a plurality of the top surfaces of the wavelength conversion members are arranged in an array.

16. The optoelectronic semiconductor component as claimed in claim 14, wherein
two adjacent top surfaces are separated from each other by the separation structure.

17. The optoelectronic semiconductor component as claimed in claim 14, wherein
a plurality of the top surfaces of the wavelength conversion members serves as a plurality of emission surfaces of the optoelectronic semiconductor component.

18. The optoelectronic semiconductor component as claimed in claim 1, wherein
each of the metal parts connects to the respective one of the light emitting chips.

19. The optoelectronic semiconductor component as claimed in claim 18, wherein
each of the metal parts has a first metal part and a second metal part.

20. The optoelectronic semiconductor component as claimed in claim 1, wherein
all of the first metal parts are connected to each other and all of the second metal parts are separated from each other.
